(19) United States
(12) Patent Application Publication
(10) Pub. No.: US 2026/0031175 A1
(43) Pub. Date: Jan. 29, 2026

(54) DIAGNOSTIC BUILT-IN SELF-TEST CIRCUIT ENHANCEMENTS FOR MEMORY ARRAYS

(71) Applicant: INTERNATIONAL BUSINESS MACHINES CORPORATION, Armonk, NY (US)

(72) Inventors: Uma SRINIVASAN, Poughkeepsie, NY (US); Daniel RODKO, Poughkeepsie, NY (US); Thomas J. KNIPS, Wappingers Falls, NY (US); Matthew Steven HYDE, Wappingers Falls, NY (US); Ivan MORADO, Poughkeepsie, NY (US)

(21) Appl. No.: 18/782,259

(22) Filed: Jul. 24, 2024

(51) Int. Cl. G11C 29/46; G11C 29/20; G11C 29/44

(52) U.S. Cl. CPC G11C 29/46; G11C 29/20; G11C 29/44

(57) ABSTRACT

Integrated circuit devices and methods of operation are provided which include a memory array having an array of memory cells arranged in rows and columns, and circuitry operatively couple to the memory array. In one aspect, the circuitry includes a fail counter circuit, and the circuitry is configured to facilitate preforming a testing operation on the memory array, with the fail counter circuit being operable during the testing operation in a selected one of a plurality of fail counter modes. The plurality of fail counter modes include an address fail counter mode to determine a number of failing addresses of the memory array during the testing operation, and a cell fail counter mode to determine the number of failing memory cells of the memory array during the testing operation. In another aspect, the circuitry includes a diagnostic column fail circuit to determine a type of column fail.

### BACKGROUND

The present invention relates generally to integrated circuit devices, and more particularly, to enhanced built-in self-test diagnostic circuitry for use in testing of memory arrays of integrated circuit devices.

Built-in self-test circuitry is commonly used as a technique to test embedded memory arrays, such as random-access memory (RAM), read-only memory (ROM), dynamic random-access memory (DRAM), synchronous dynamic random-access memory (SDRAM), etc. The built-in self-test circuitry facilitates memory fault testing of the array by adding or associating logic with the memory array circuit within the integrated circuit device to improve its testability for memory array failures. The built-in self-test circuitry generates one or more built-in self-test patterns in the memory array and reads them back to log any memory defects. The built-in self-test circuitry allows an integrated circuit device to generate and apply tailored test patterns, which simplifies the testing process, and increases test coverage compared with, for instance, externally applied testing approaches.

### SUMMARY

Certain shortcomings of the prior art are overcome, and additional advantages are provided herein through the provision of an integrated circuit device which includes a memory array having an array of memory cells arranged in rows and columns, and circuitry operatively coupled to the memory array. The circuitry, which includes a fail counter circuit, is configured to facilitate performing a testing operation on the memory array, with the fail counter circuit being operable during the testing operation in a selected one of a plurality of fail counter modes. The plurality of fail counter modes include an address fail counter mode to determine a number of failing addresses of the memory array during the testing operation, and a cell fail counter mode to determine a number of failing memory cells of the memory array during the testing operation.

In another aspect, an integrated circuit device is provided which includes a memory array having multiple subarrays of memory cells arranged in rows and columns, and circuitry operatively coupled to the memory array. The circuitry, which includes a diagnostic column fail circuit, is configured to facilitate performing a testing operation on the memory array, with the diagnostic column fail circuit being operable during the testing operation to determine a type of column fail, with the type of column failing being one of a local column fail and a global column fail. The local column fail is determined by the diagnostic column fail circuit where a column fails testing across multiple rows that are different rows across a same subarray and across different subarrays of the multiple subarrays. The global column fail is determined by the diagnostic column fail circuit where a column fails testing across multiple rows and on a same row across different subarrays of the multiple subarrays.

In a further aspect, a method of testing an integrated circuit device is provided. The integrated circuit device has a memory array including an array of memory cells arranged in rows and columns, and circuitry operatively coupled to the memory array, where the circuitry includes a fail counter circuit. The method includes selecting a fail counter mode of the fail counter circuit from a plurality of fail counter modes. The plurality of fail counter modes include an address fail counter mode to determine a number of failing addresses of the memory array during a testing operation, and a cell fail counter mode to determine a number of failing memory cells of the memory during the testing operation. In addition, the method includes performing the testing operation on the memory array, with the fail counter circuit operable during the testing operation in the selected one of the plurality of fail counter modes.

Additional features and advantages are realized through the techniques described herein. Other embodiments and aspects are described in detail herein and are considered a part of the claimed aspects.

### BRIEF DESCRIPTION OF THE DRAWINGS

One or more aspects are particularly pointed out and distinctly claimed as examples in the claims at the conclusion of the specification. The foregoing and objects, features, and advantages of one or more aspects are apparent from the following detailed description taken in conjunction with the accompanying drawings in which:

FIG. 1 depicts one example of a computing environment to include and/or use one or more aspects of the present disclosure;

FIG. 2A depicts one embodiment of a fail counter circuit for built-in self-test circuitry of a memory array of an integrated circuit device, in accordance with one or more aspects of the present disclosure;

FIG. 2B depicts one example of a result register state, of a result register of the fail counter circuit of FIG. 2A, during a testing operation, in accordance with one or more aspects of the present disclosure;

FIG. 2C depicts one embodiment of a fail counter circuit workflow, in accordance with one or more aspects of the present disclosure;

FIG. 2D depicts an example operation of the fail counter circuit of FIGS. 2A-2C in an address fail counter mode during the testing operation, in accordance with one or more aspects of the present disclosure;

FIG. 2E depicts one embodiment of cycle timing for a built-in self-test of the memory array with the fail counter circuit in address fail counter mode, in accordance with one or more aspects of the present disclosure;

FIG. 2F depicts an example operation of the fail counter circuit of FIGS. 2A-2C in a cell fail counter mode during the testing operation, in accordance with one or more aspects of the present disclosure;

FIG. 2G depicts one embodiment of cycle timing for a built-in self-test of the memory array with the fail counter circuit in cell fail counter mode, in accordance with one or more aspects of the present disclosure;

FIG. 3A depicts one embodiment of a memory array with multiple subarrays to be built-in self-tested and for which a diagnostic column fail circuit is to determine a type of column fail, in accordance with one or more aspects of the present disclosure;

FIG. 3B depicts the memory array of FIG. 3A with several cells identified by the diagnostic column fail circuit as having failed a testing operation, in accordance with one or more aspects of the present disclosure;

FIG. 3C depicts a table for the test example of FIG. 3B, where the diagnostic column fail circuit determines that the test fails in the failing cell column are local column fails, in accordance with one or more aspects of the present disclosure;

FIG. 3D depicts another test example of the memory array of FIG. 3A, where the diagnostic column fail circuit determines that test fails in the failing cell column are a global column fail, in accordance with one or more aspects of the present disclosure;

FIG. 3E depicts a table for the test example of FIG. 3D, where the diagnostic column fail circuit determines that the test fails in the failing cell column are a global column fail, in accordance with one or more aspects of the present disclosure;

FIG. 3F depicts one embodiment of a diagnostic column fail circuit for built-in self-test circuitry of a memory array of an integrated circuit device, in accordance with one or more aspects of the present disclosure;

FIG. 3G depicts one embodiment of a diagnostic column fail circuit workflow, in accordance with one or more aspects of the present disclosure;

FIG. 4 is an overview diagram of a design process used in semiconductor design, manufacture, and test, in accordance with one or more aspects of the present disclosure;

FIG. 5 depicts a further example of integrated circuit fabrication processes, in accordance with one or more aspects of the present disclosure; and

FIG. 6 shows an exemplary high level electronic design automation (EDA) tool flow, through which one or more aspects of the present disclosure can be implemented.

### DETAILED DESCRIPTION

Aspects of the present disclosure and certain features, advantages, and details thereof, are explained more fully below with reference to the non-limiting example(s) illustrated in the accompanying drawings. Descriptions of well-known systems, devices, circuits, processing techniques, tools, etc., are omitted so as not to unnecessarily obscure the disclosure in detail. It should be understood, however, that the detailed description and the specific example(s), while indicating aspects of the disclosure, are given by way of illustration only, and are not by way of limitation. Various substitutions, modifications, additions, and/or arrangements, within the spirit and/or scope of the underlying inventive concepts will be apparent to those skilled in the art for this disclosure. Note further that reference is made below to the drawings, where the same or similar reference numbers used throughout different figures designate the same or similar components. Also, note that numerous inventive aspects and features are disclosed herein, and unless otherwise inconsistent, each disclosed aspect or feature is combinable with any other disclosed aspect or feature as desired for a particular application of the concepts disclosed.

Note also that illustrative embodiments are described below using specific circuits, code, designs, architectures, protocols, layouts, schematics, systems, or tools only as examples, and not by way of limitation. Furthermore, the illustrative embodiments are described in certain instances using particular logic circuits, software, hardware, tools, and/or data processing environments only as example for clarity of description. The illustrative embodiments can be used in conjunction with other comparable or similarly purposed structures, systems, applications, architectures, etc. One or more control aspects of an illustrative embodiment can be implemented in hardware or software or a combination thereof.

As understood by one skilled in the art, program code or program instructions, as referred to in this application, can include software and/or hardware. For example, program code in certain embodiments of the present disclosure can utilize a software-based implementation of the functions described, while other embodiments can include fixed function hardware. Certain embodiments combine both types of program code.

One or more aspects of the present disclosure are incorporated in, performed and/or used within a computing environment. As examples, the computing environment can be of various architectures and of various types, including, but not limited to: personal computing, client-server, distributed, virtual, emulated, partitioned, non-partitioned, cloud-based, quantum, grid, time-sharing, clustered, peer-to-peer, mobile, having one node or multiple nodes, having one processor or multiple processors, and/or any other type of environment and/or configuration, etc., that includes a memory array and circuitry such as disclosed herein. Aspects of the present disclosure are not limited to a particular architecture or environment.

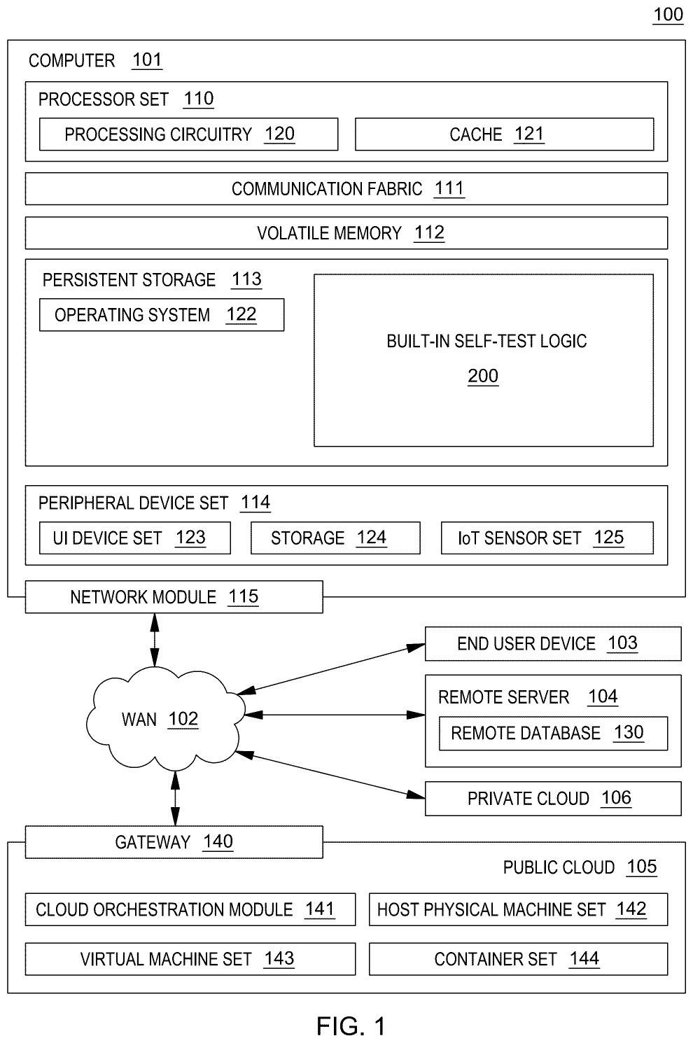

Prior to further describing detailed embodiments of the present disclosure, an example of a computing environment to include and/or use one or more aspects of the present disclosure is discussed below with reference to FIG. 1.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as built-in self-test logic block 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions (or logic) for performing the inventive methods may be stored (or located) in block 200 in persistent storage 113.

Communication fabric 111 is the signal conduction path that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 200 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 103 is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Cloud computing services and/or microservices (not separately shown in FIG. 1): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to an “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks

The computing environment described above is only one example of a computing environment to incorporate, perform and/or use one or more aspects of the present disclosure. Other examples are possible. Further, in one or more embodiments, one or more of the components/modules of FIG. 1 need not be included in the computing environment and/or are not used for one or more aspects of the present disclosure. Further, in one or more embodiments, additional and/or other components/modules can be used. Other variations are possible.

Note that built-in self-test logic, including the built-in diagnostic circuits described herein, can be used in association with a variety of memory arrays in various locations within a computing environment, such as computing environment 100 depicted in FIG. 1, by way of example only. In one or more implementations, the diagnostic built-in self-test circuits disclosed herein can be used in association with built-in self-test logic for a variety of embedded memory arrays of a computing environment, such as random-access memory (RAM), read-only memory (ROM), dynamic random-access memory (DRAM), synchronous dynamic random-access memory (SDRAM), etc., in a variety of locations on a variety of integrated circuit devices of the computing environment.

Conventionally, an integrated circuit device, such as a semiconductor memory device, includes an array of memory cells arranged in rows and columns. In one or more implementations, a memory array can be divided into multiple subarrays of memory cells arranged in rows and columns. Memory cells in an array can be selected for reading and writing via row and address column signals input to the memory device. The row and address column signals are processed by address decoding circuitry which selects the appropriate row lines and column lines in the array to access a desired memory cell or memory cells.

As part of fabricating, and/or after fabricating, of an integrated circuit with embedded memory, such as a semiconductor memory device, the circuit can be tested at various stages. For instance, in one or more embodiments, an integrated circuit can be connected to a tester with a probe card when the circuit is still in wafer form. Further, after the circuit has been diced and packaged, the circuit can be placed into sockets on a load board. The load board is then placed on a test head, which is connected through a cable to a high-speed tester so the tester can apply signals to and receive signals from the circuit.

In addition, or alternately, a semiconductor memory device can be configured with built-in self-test logic, or memory built-in self-test logic. The built-in self-test logic is configured to generate patterns in a memory array, and read the patterns back to identify and log any potential memory defects. The built-in self-test logic can include repair and redundancy capabilities, and allow testing of a memory array with a high degree of fault coverage. The testing algorithm or process used in the built-in self-test logic can be implemented in embedded circuitry in the memory device, such as logic associated with one or more memory arrays of a memory device. With built-in self-test logic, a test pattern generator and test response analyzer are incorporated directly into the memory device to be tested. At the end of a conventional built-in self-test run, a pass or fail signal can be asserted indicating whether the memory device passes or fails the test. Intermediate pass and/or fail signals can also be provided, allowing individual memory arrays, rows, columns, cells, etc. to be further analyzed.

For instance, in one or more embodiments, an integrated circuit device can include an array of read/write memory having a plurality of memory cells, with each memory cell having a unique address. In addition, the memory device can include built-in self-test circuitry including, for instance, a built-in self-test engine. In one or more embodiments, the built-in self-test engine includes a controller responsive to a test enable signal and operative to generate and store test data in the memory array. The built-in self-test engine further includes a comparator, a diagnostic unit, and a built-in self-test clock. The comparator is operative to compare retrieved data read from the memory array and the test data during a single pass test, where the comparator identifies failed cycles where the retrieved data does not correspond to the test data. The diagnostic unit is operative to store the failed cycles and is operative to store failed data and failing addresses during a single pass test. In conventional embodiments, the built-in self-test engine typically stops at each fail cycle during the single pass test. For instance, the built-in self-test clock typically operates to receive signals from the comparator when fail cycles are identified by the comparator, and the signals gate off the built-in self-test clock, thereby stopping the built-in self-test engine at each failed cycle.

In one or more conventional self-test implementations, a failed row address can be captured, and row redundancy used to compare a failed row address. If there is a column failure on a die, the built-in self-test circuitry can set a flag to identify the failure as a column failure, but does not give any indication about the severity of the column failure, i.e. if there are few bits failing in a column or all bits failing in a column. A more severe column fail could potentially drive a different corrective action.

When running a built-in self-test for a memory array, it is advantageous to describe the fail accurately and without additional debug or testing required to collect statistics on what type of failure mechanism affects the array on volume data. It would be desirable to have the test results immediately available, and not have to execute a separate test path in order to collect further data when there is a test failure. This is true both for classifying a type of column fail, as well as determining a number of address fails found, both of which can be challenging to accomplish at speed, that is, without or absent stopping of the running of a built-in self-test pattern. Currently, as noted, the solutions typically stop the test when a fail is found, dump the test fail data, then restart the test to collect further fails, etc. This is a much slower process than an at speed (i.e., at testing operation speed) collection of fail data and fail statistics, and providing of diagnostics information. Although it is currently possible to detect with built-in self-test diagnostic circuitry whether a given fail is a row or column fail, or a single bit fail, no information about the subtype of the column fail is able to be collected. Typically, further debugging is required to fully describe a column fail, that is, whether it is a few neighboring fail bits in a column (or a local column fail), or more spread out, in which case it could be a global column fail issue.

Disclosed herein, in one or more embodiments, are integrated circuit devices with enhanced built-in self-test diagnostic circuitry. For instance, in one or more embodiments, a fail counter circuit and bitmap methodology are disclosed that generate further details regarding a number of fails for a given test operation, and/or a diagnostic column fail circuit is disclosed which generates column fail characteristics, beyond just a column fail, to indicate whether the column fail is a local column fail or a global column fail, both of which are accomplished with the addition of a few logic gates or circuits, and with the data being collected and logged at operational test speed, that is, absent stopping of the running of the built-in self-test operation once started.

In one or more embodiments, disclosed herein is an integrated circuit device which includes a memory array including an array of memory cells arranged in rows and columns, and circuitry operatively coupled to the memory array. The circuitry includes a fail counter circuit, and the circuitry is configured to facilitate performing a testing operation on the memory array, with a fail counter circuit being operable during the testing operation in a selected one of a plurality of fail counter modes. The plurality of fail counter modes include an address fail counter mode to determine a number of failing addresses of the memory array during the testing operation, and a cell fail counter mode to determine a number of failing memory cells of the memory cell array during the testing operation.

In one embodiment, the fail counter circuit is configured with a fail counter control to facilitate selection of one fail counter mode of the plurality of fail counter modes.

In one or more embodiments, the circuitry includes built-in self-test circuitry, and the selected one fail counter mode is the address fail counter mode, where performing the testing operation on the memory array with the fail counter circuit in the address fail counter mode includes running a built-in self-test pattern on the memory array and incrementing a fail counter of the fail counter circuit based on each failing address during the testing operation.

In one or more embodiments, the fail counter circuit determines the number of failing addresses in the address fail counter mode at testing operation speed, absent a stopping of the running of the built-in self-test pattern once started.

In one or other embodiments, the circuitry includes built-in self-test circuitry and the selected one fail counter mode is the cell fail counter mode, where performing the testing operation on the memory array with the fail counter circuit in the cell fail counter mode includes running a built-in self-test pattern on the memory array and incrementing a fail counter of the fail counter circuit based on each failing memory cell during the testing operation. In one or more embodiments, the fail counter circuit determines the number of failing memory cells of the memory array in the cell fail counter mode at testing operation speed, absent a stopping of the running of the built-in self-test pattern.

In one or more embodiments, the circuitry is further configured to facilitate performing the testing operation on the memory array in the cell fail counter mode absent stopping running of the built-in self-test pattern by inserting N no-operation cycles in the built-in self-test pattern used in the testing operation after memory array read of the testing operation to facilitate the fail counter circuit processing up to N potential failing cells at each memory array address, where each memory array address includes N bits.

In one or more embodiments, the memory array includes multiple subarrays of the memory cells arranged in rows and columns, and the circuitry further includes a diagnostic column fail circuit. The diagnostic column fail circuit is operable during the testing operation to determine a type of column fail, where the type of column fail is one of a local column fail and a global column fail. The local column fail is determined by the diagnostic column fail circuit where a column fails testing across multiple rows that are different rows across a same subarray and across different subarrays of the multiple subarrays. The global fail is determined by the diagnostic column circuit where a column fails testing across multiple rows and on a same row across different subarrays of the multiple subarrays.

In one or more embodiments, performing the testing operation on the memory array includes running a built-in self-test pattern on the memory array, with the diagnostic column fail circuit determining the type of column fail during the testing operation at testing operation speed, absent a stopping of the running of the built-in self-test pattern.

In one or more other aspects, an integrated circuit device is provided with includes a memory array including multiple subarrays of memory cells in rows and columns, and circuitry operatively coupled to the memory array. The circuitry includes a diagnostic column fail circuit, and the circuitry is configured to facilitate performing a testing operation on the memory array, with the diagnostic column fail circuit being operable during the testing operation to determine a type of column fail, where the type of column fail is one a local column fail and a global column fail. The local column fail is determined by the diagnostic column fail circuit where a column fails testing across multiple rows that are different rows across a same subarray and across different subarrays of the multiple subarrays. The global column fail is determined by the diagnostic column fail circuit where a column fails testing across multiple rows and on a same row across different subarrays of the multiple subarrays. In one or more embodiments, performing the testing operation on the memory includes running a built-in self-test pattern on the memory array, where the diagnostic column fail circuit determines the type of column fail during the testing operation at testing operation speed, absent a stopping of the running of the built-in self-test pattern.

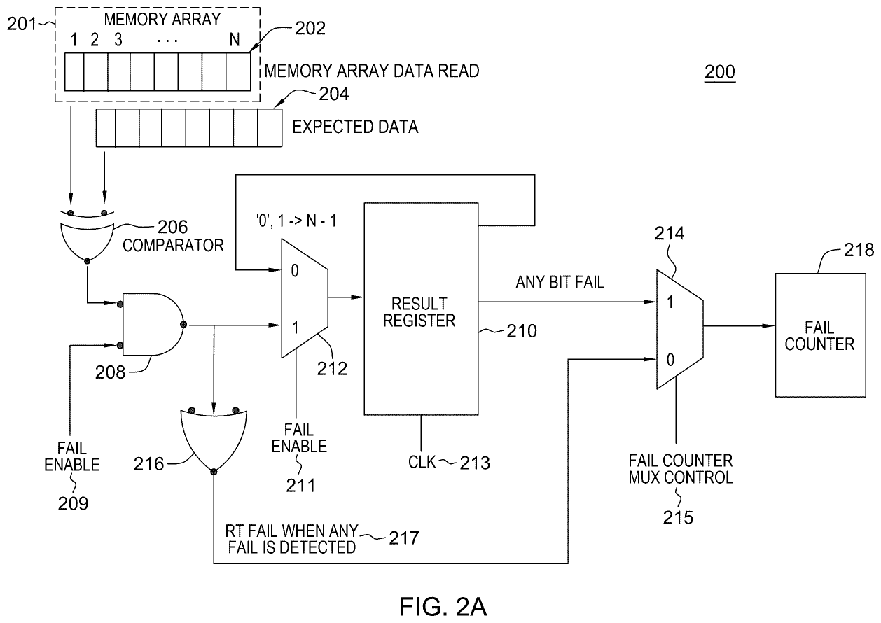

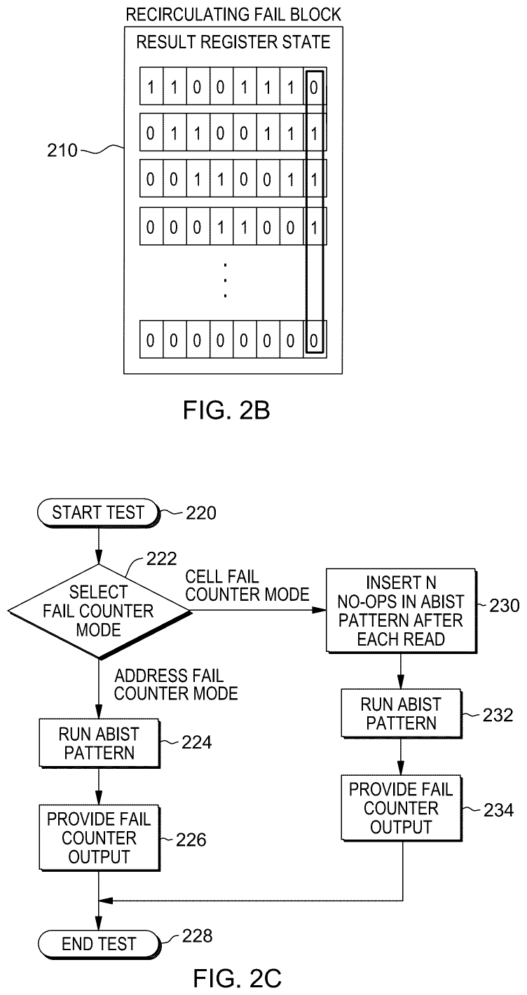

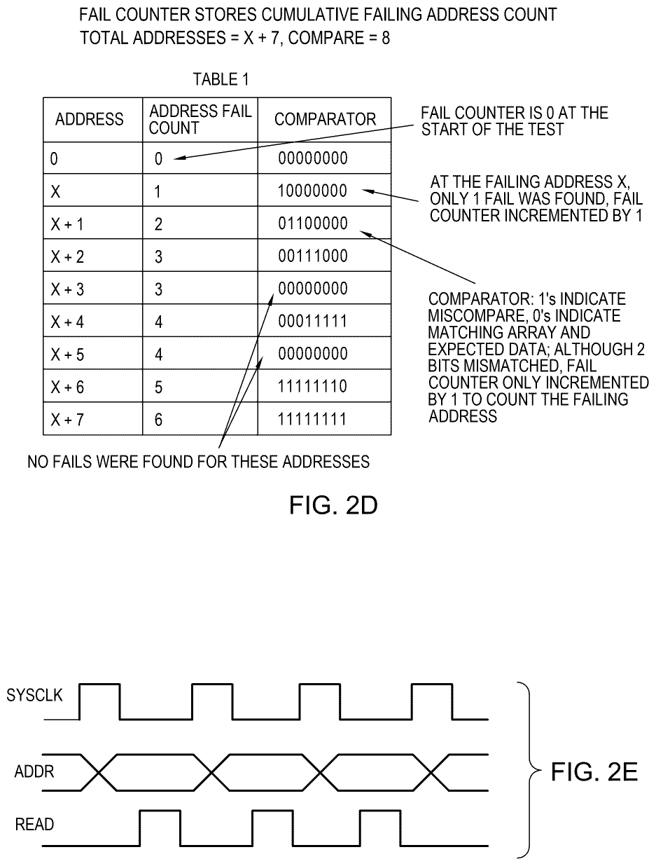

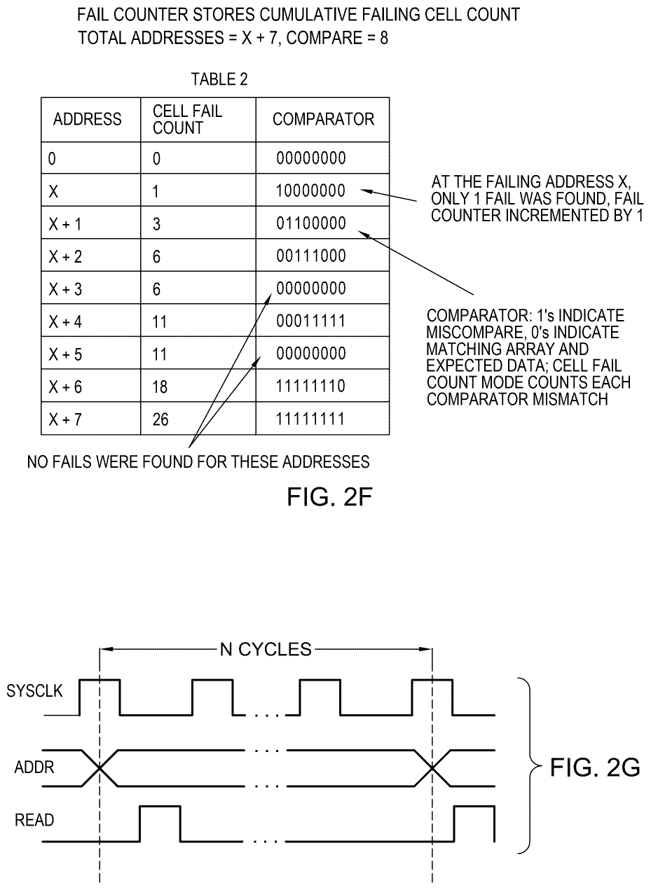

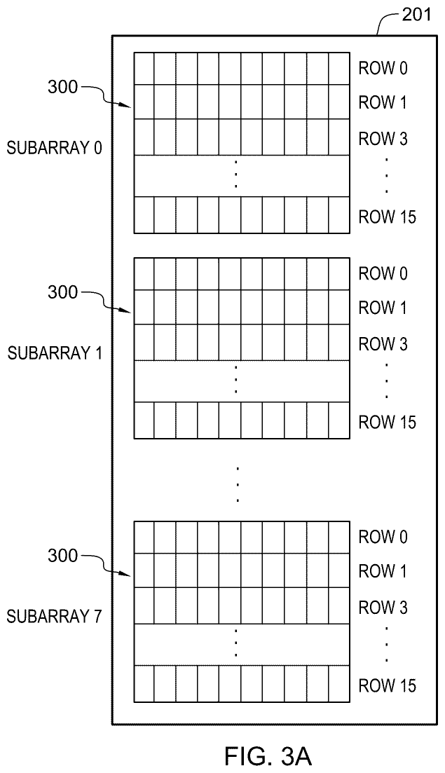

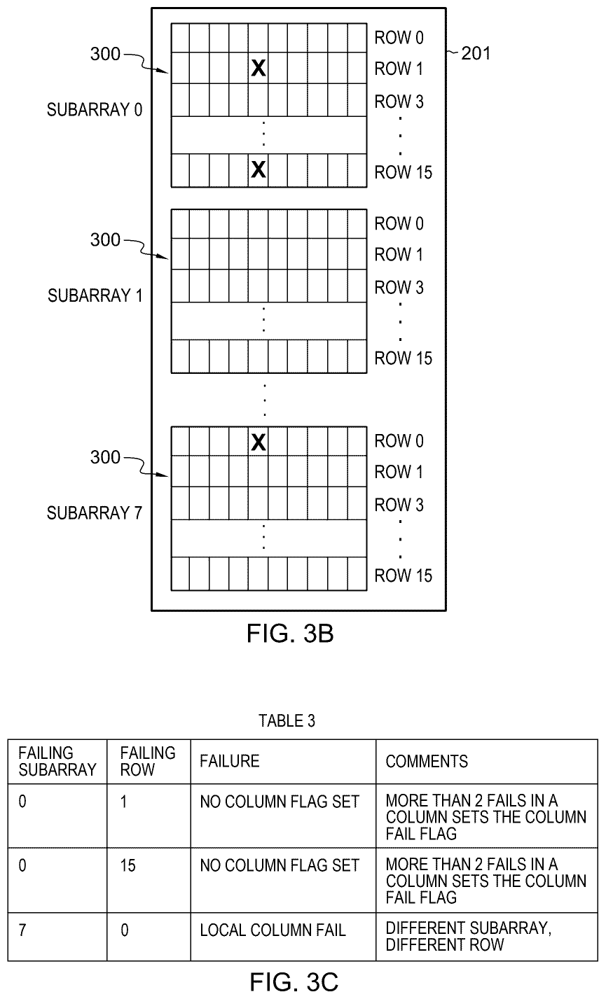

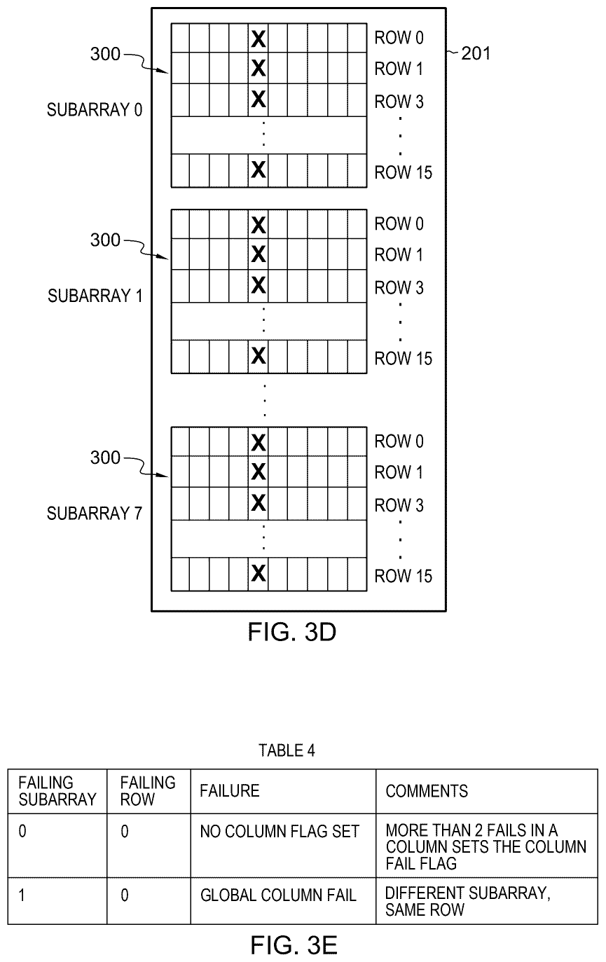

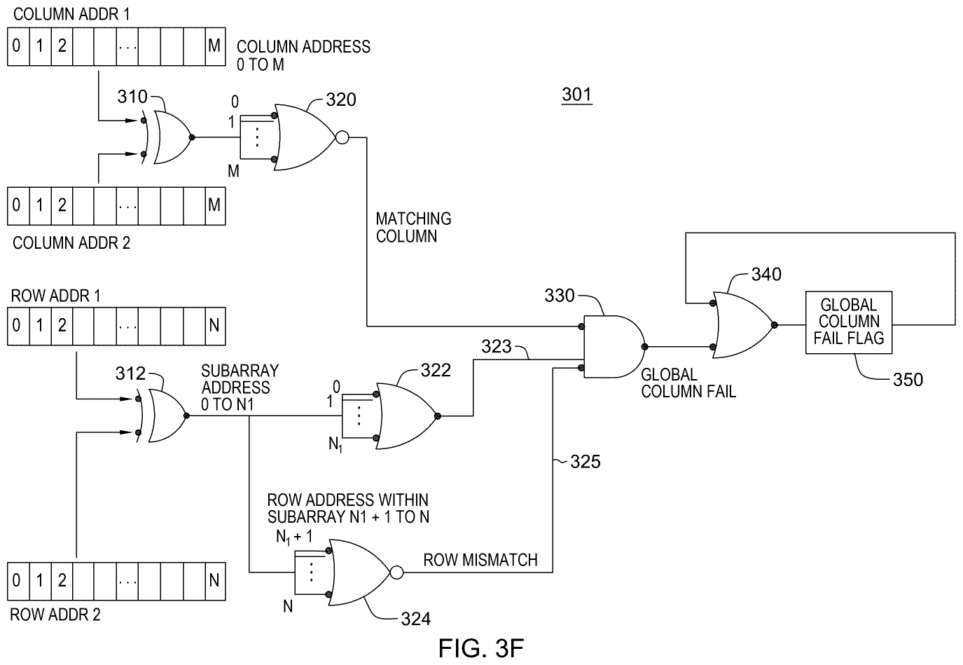

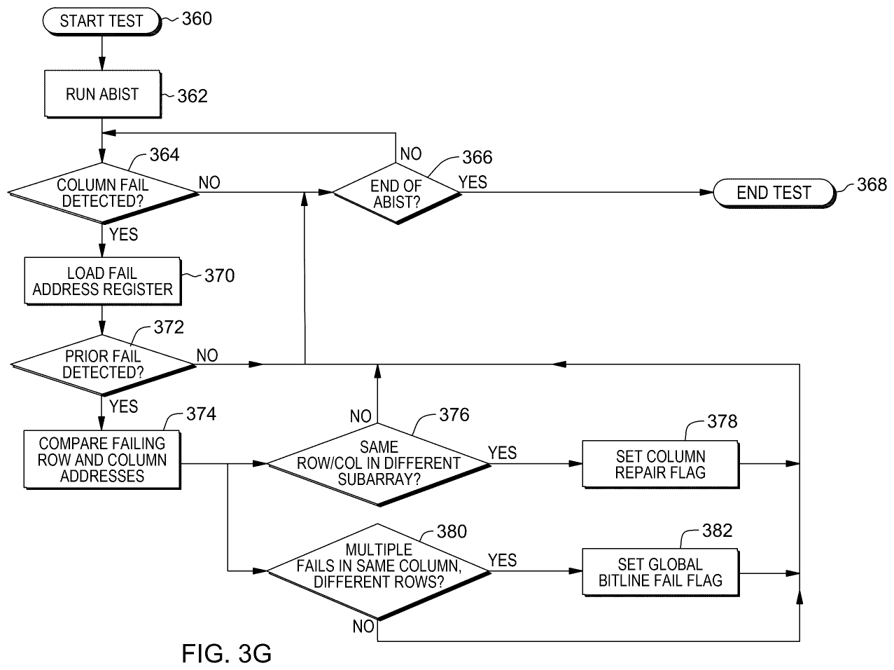

As described herein, various embodiments disclosed relate to integrated circuit device testing. More specifically, various embodiments relate to diagnostic built-in self-test circuitry including a fail counter circuit operable in a selected one of a plurality of fail counter modes. The plurality of fail counter modes include an address fail counter mode to determine a number of failing addresses of the memory array during the testing operation, and a cell fail mode to determine a number of failing memory cells of the memory array during the testing operation. One example embodiment of a fail counter circuit and method for use in built-in self-test is depicted in FIGS. 2A-2G, and described further below. In one or more additional, or alternative, embodiments, an integrated circuit device is disclosed with built-in self-test and an associated diagnostic column fail circuit. The built-in self-test is configured to facilitate performing a testing operation on the memory array, and the diagnostic column fail circuit is operable during the testing operation to determine a type of column fail, with the type of column fail being one of a local column fail and a global column fail. The local column fail is determined by the diagnostic column fail circuit where a column fails testing across multiple rows that are different rows across a same subarray and across different subarrays of the multiple subarrays. The global column fail is determined by the diagnostic column fail circuit where a column fails testing across multiple rows and on a same row across different subarrays of the multiple subarrays. FIGS. 3A-3G depict one embodiment of a memory array with a diagnostic column fail circuit such as disclosed herein, in accordance with one or more aspects of the present disclosure.

As noted, FIGS. 2A-2G depict one embodiment of a fail counter circuit 200 (FIG. 2A) for inclusion in, or operatively coupling to, built-in self-test circuitry for a memory array, in accordance with one or more aspects disclosed herein. Fail counter circuit 200 represents one embodiment only of a diagnostic fail counter circuit, such as disclosed. In the embodiment of FIG. 2A, fail counter circuit 200 can be part of test circuitry operatively coupled to memory array 201, which includes an array of memory cells arranged in rows and columns, where a memory address at a memory cell has N bits, where N is 8-bits, by way of example only. As illustrated, fail counter circuit 200 includes a comparator 206 which compares memory array read data 202 with expected data 204 during a testing operation on the memory array using, for instance, a built-in self-test pattern. In the embodiment of FIG. 2A, a fail enable signal 209 controls an AND gate 208 which allows the output of comparator 206 to begin being counted by a recirculating fail block, which includes, a result register 210 and a multiplexer 212 at the input of the result register. In one embodiment, any fail is output to a fail counter 214. A fail enable signal 211 controls multiplexer 212, which receives as input the output from AND gate 208 as well as recirculated data back from result register 210. A clock signal 213 is also provided to clock result register 210.

An RT FAIL signal 217 is sent at the output of an OR gate 216 when any fail is detected in the output of the comparator 206. A fail counter mux control signal 215 controls storing either a number of failing addresses of the memory array during the testing operation in an address fail counter mode or a number of failing memory cells of the memory array during the testing operation in a cell fail counter mode, such as described herein. By way of example only, a mux control=0 signal denotes an address fail counter mode, and a mux control=1 signal denotes the cell fail counter mode. In one or more other embodiments, the control signal definitions can be reversed.

FIGS. 2A & 2B depict an example of a result register 210 state, where the recirculating fail block, including result register 210 and mux 212, shows how the failing cells are counted one at a time in each row access. The register contents are shifted right and the least significant bit if “1” increments the fail counter 218 by 1 in the case of an address fail counter mode counting operation. In the case where the fail counter mux control 215=1, that is, where the fail counter circuit 200 is in cell fail counter mode, then in a given row access of N data bits, each bit with a status 1 from the comparator 206 is counted as a failing cell by the fail counter 218. In this manner, depending on the fail counter mux control value setting, the fail counter circuit 200 is operable to either determine a number of failing addresses of the memory array during the testing operation or a number of failing memory cells of the memory array during the testing operation. Using the same circuitry in different modes, and repeating the testing operation, the fail counter circuit can provide both the number of the failing addresses of the memory array and the number of failing memory cells of the memory array.

FIGS. 2A-2C depict one embodiment of a fail counter circuit workflow, in accordance with aspects of the present disclosure. Upon starting a test on the memory array, such as a built-in self-test operation, a control value is selected or obtained to determine the fail counter circuit mode 222. In the embodiment of FIG. 2A, this is accomplished via the fail counter mux control setting 215, which in one embodiment only, is set to ‘0’ for an address fail counter mode, and ‘1’ for a cell fail counter mode. Assuming that the fail counter circuit is set to address fail counter mode, then a built-in self-test pattern, or array built-in self-test (ABIST) pattern, is run 224 as desired for testing of the particular memory array, with the fail counter circuit determining a fail counter output 226 provided, for instance, to further diagnostic circuitry, repair circuitry, and/or a display for feedback to an operator, etc., upon completion of running the pattern, which ends the test 228.

As noted, in one or more embodiments, the cell fail counter mode is selected, or controlled, for instance, based on the fail counter mux control 215 signal in the fail counter circuit 200 of FIG. 2A. In one embodiment, where the mux control value equals ‘1’, then the cell fail counter mode is selected. Assuming N is the number of bits in a memory array read address, and thus, the number of read data bits being compared by the comparator, then a minimum of N cycles are inserted between memory array reads to process the N bits of each memory read address. In one or more embodiments, the method includes inserting N no-operation cycles in the built-in self-test (BIST) pattern or array built-in self-test (ABIST) pattern, after each read 230. In this manner, the built-in self-test pattern 232 is run on the memory array and the fail counter of the fail counter circuit is incremented based on each failing cell during the testing operation at testing operation speed, that is, absent a stopping of the running of the built-in self-test pattern to process a detected fail. As illustrated, the fail counter output is provided 234, for instance, to further diagnostic circuitry, to repair circuitry, and/or a display for feedback to an operator, etc., which ends the test operation 228.

By way of further example, Table 1 of FIG. 2D depicts example results of the fail counter circuit of FIGS. 2A-2C in address fail counter mode during performing a testing operation on a memory array. In this mode, the fail counter stores a cumulative count of the failing addresses of the memory array. In the depicted embodiment, the total addresses are equal to X+7, with the compare being an 8-bit compare in the case where the memory address is 8-bits wide. As indicated, the fail counter begins at 0 at the start of the testing operation. At failing address X, only one fail is found, and thus, the fail counter is incremented by 1. In the depicted embodiment, a ‘1’ output from the comparator indicates a miss-compare, while a ‘0’ indicates a matching of the array and expected data. At address X+1 two bits are mismatched, but the fail counter is only incremented by 1 to account for the failing address. Note that addresses X+3 and X+5 have no failing bits from the comparator and hence the address fail count does not increment from the data in these addresses.

FIG. 2E depicts one embodiment of cycle timing for a testing operation of the memory array with the fail counter circuit in address fail counter mode such as discussed in connection with the example of FIG. 2D. In address fail counter mode, the fail counter mux control bit 215 (FIG. 2A) is set to ‘0’ (in one embodiment), and the counter input is the RT FAIL signal, with the minimum test cycles between read operations being one test cycle.

FIG. 2F depicts in Table 2 an example operation of the fail counter circuit of FIGS. 2A-2C in cell fail counter mode during the testing operation. In this mode, the fail counter stores a cumulative failing cell count. The total addresses to be evaluated are assumed to be X+7, and the number of bits in each address to be compared are 8, by way of example only. As illustrated, at failing address X only one fail is found at the comparator output, at which point the fail counter is incremented by one. Note in this regard, that a ‘1’ output from the comparator indicates a miss-compare, and ‘0’ indicates a matching bit of the memory array and the expected data. Note also that this is one example only. In this mode, the fail counter circuit counts each comparator mismatch. Where no fails are found at an address, such as at address X+3 and address X+5 in the example, the fail counter does not increment.

FIG. 2G depicts one embodiment of cycle timing for a testing operation of the memory array with a fail counter circuit in cell fail counter mode, such as described herein. In this mode, the fail counter control bit or mux control bit 215 (FIG. 2A) is set to 1 (in one example), and the counter input controlling the count is the RECIRC FAIL signal output by the result register 210. Further, note that as discussed herein, in the cell fail counter mode the minimum cycles between read operations is set to N cycles, where N is the number of bits at a memory read address of the memory array being tested.

As noted, in one or more additional, or alternative, embodiments, an integrated circuit device is disclosed herein with built-in self-test and an associated diagnostic column fail circuit. The built-in self-test is configured to facilitate performing a testing operation on the memory array, and the diagnostic column fail circuit is operable during the testing operation to determine a type or class of column fail, with the type of column fail being one of a local column fail and a global column fail. The local column fail is determined by the diagnostic column fail circuit where a fail column fails testing across multiple rows that are different rows across a same subarray and across different subarrays of the multiple subarrays. The column global fail is determined by the diagnostic column fail circuit where a column fails testing across multiple rows and on a same row across different subarrays of the multiple subarrays. FIGS. 3A-3G depict one embodiment of a memory array with a diagnostic column fail circuit, such as disclosed herein.

As illustrated in FIG. 3A, one embodiment of a memory array with multiple subarrays to be built-in self-tested with a diagnostic column fail circuit such as described is depicted. In the embodiment illustrated, the memory array 201 is divided into multiple subarrays 300, such as the eight illustrated subarrays. Each subarray includes an array of memory cells arranged in rows (row 0 . . . row 15) and columns. In the example illustrated, each subarray contains the same number of rows, for instance, 16 rows in one example, and the same number of columns, such as 8 columns, 10 columns, etc. As explained herein, a column fail is triggered when there are N fails in a same column as dictated by the memory array design, where N can be, for instance, two or more. In one or more embodiments, further information regarding a column fail is also generated, that is, whether the column fail is a local column fail or a global column fail. In one or more embodiments, a local column fail flag can be set where it is determined by the diagnostic column fail circuit that the failing column cells represent a local column fail, and a global column fail flag can be set where it is determined by the diagnostic column fail circuit that the column fails represent a global column fail.

FIG. 3B illustrates an example local column fail, where there are multiple memory bits failing in the same column across multiple rows, but different rows across the same or different subarrays. In this case, the global column fail flag is not set, and the fail is determined to be a local column fail. As illustrated in FIG. 3B, and by way of example only, column 4 (of column 0 . . . column 9) fails in row 1 and row 15 on subarray 0 and on row 0 on subarray 7. Although a column fail flag is set, such as to indicate the need for the device to perform a column repair (or replace), this is not a global column fail.

FIG. 3C depicts Table 3 for the test example of FIG. 3B, with the failing addresses and flags to be activated for a local column fail noted. In this illustration, it is assumed that there are 8 subarrays, and 16 rows per subarray, as illustrated in FIGS. 3A-3B. As described herein, a local column fail is determined by the diagnostic column fail circuit where the column fails testing across multiple rows that are different rows across a same subarray and across different subarrays of the multiple subarrays. Thus, in failing subarray 0, failing row 1 is identified in one column, with no column flag being set, and in the same column of subarray 0, failing row 15 is identified by the circuit without a column flag being set. Upon identifying in the same column in failing row subarray 7, row 0, a failure, then a local column fail is identified, and in one embodiment, the column repair flag is set, and/or a local column flag can be set.

As a further example, FIG. 3D depicts the memory array of FIGS. 3A-3B, with further memory cells being identified as failing in the same column. As described herein, a global column fail is identified where the same column fails across multiple rows and on the same row across different subarrays. In this case, a global column fail flag is set, with the fail being determined to be a global column fail. In the example of FIG. 3D, column 4 fails in row 0 on subarray 0, and in all subsequent rows as well, and the same is true for the rest of the subarrays. The column fail flag is set because at least 2 fails were found by the circuit on the same column, and the global column fail flag is also set where the column fails testing across multiple rows and on a same row across different subarrays of the multiple subarrays. Although all memory bits are failing in the same column in the example FIG. 3D, the same process occurs where sparse bits fail across a column, but span multiple subarrays as described, indicating a general global bit line issue.

FIG. 3E depicts a Table 4 for the test example of FIG. 3D, where the diagnostic column fail circuit determines that the test fails in the failing cell column are a global column fail. In the illustrated example, the 8 subarrays and 16 rows per subarray example of FIGS. 3A-3B & 3D are used. As illustrated in Table 4, the failing rows in subarray 0 set the column fail flag since 2 fails in the same column and the same subarray are identified. Once failing subarray 1, failing row 0 is determined by the circuit, then the global column fail flag is set since cells in different subarrays on the same row are identified by the circuits failing.

FIG. 3F depicts one embodiment of a diagnostic column fail circuit 301 for a built-in self-test circuitry of a memory array of an integrated circuit device, in accordance with one or more aspects disclosed herein. In one or more embodiments, diagnostic column fail circuit 301 is operatively coupled to a memory array, such as memory array 201 of FIG. 2A and is part of, or associated with, built-in self-test circuitry for the memory array. Note that diagnostic column fail circuit 301 represents one embodiment only of a diagnostic column fail circuit, such as disclosed. In the embodiment of FIG. 3F, the built-in self-test circuitry, including diagnostic column fail circuit 301, is operatively coupled to an array of memory cells arranged in multiple subarrays arranged in rows and columns. In the embodiment illustrated, diagnostic column fail circuit 301 includes a comparator 310 providing input to a NOR gate 320 which provides a matching column signal output when a column address, that is address 0 . . . M, matches a prior column address. Note in this regard that both for the local column fail determination and the global column fail determination the read column address and prior column address need to match, that is, the fails at issue are within the same column of the memory array. Diagnostic column fail circuit 301 includes another comparator 312 which compares failing row addresses and provides input to OR gate 322 and NOR gate 324 which respectively receive subarray addresses 0 to N₁ and row addresses within subarray N₁+1 to N. NOR gate 320, OR gate 332 and NOR gate 324 provide input to AND gate 330, which provides an output global fail signal to an OR gate 340, which drives the global column fail flag 350. In the case of a local column fail, NOR gate 320 indicates a matching column, and there is a row address within a subarray mismatch as determined at the output of NOR 324. In this case, the subarray mismatch signal 323 from OR gate 322 is a don't care signal. As noted, in the case of a local column fail determination only, the global column fail output OR gate 340 is 0 and the global column fail flag remains unset.

In the case of a global column fail determination, there is again a column address matching signal at the output of NOR gate 320, and in addition, there is a row address match signal 325 at the output of NOR gate 324, and a subarray mismatch signal 323 at the output of OR gate 322. For instance, in one or more embodiments, if subarray 1 has a same local row fail as subarray 0, then the global column fail flag is set, and subsequent matching row fails 325 are a don't care since the flag is already loaded, such as in a latch. In this case, the global column fail flag output is true or 1 meaning that the diagnostic column fail circuit has identified the failing cells of the column as indictive of a global column fail, rather than simply a local column fail.

FIG. 3G depicts one embodiment of a diagnostic column fail circuit workflow, in accordance with one or more aspects disclosed herein. Upon starting a test 360 on a memory array, a built-in self-test pattern, such as an array built-in self-test pattern, is run 362. During the testing operation, the diagnostic column fail circuit processes the test data to determine whether a column fail has been detected 364. If “no”, then processing determines whether the built-in self-test pattern has finished 366. If “yes”, then the test ends 368. Assuming that the built-in self-test pattern run is not finished, the process continues until a column fail is detected 364, in which case the fail address is loaded into a register 370. Processing determines whether there is a prior fail address loaded 372. If “no”, then the process returns to determine whether the end of the built-in self-test pattern run has been reached. This process continues until it is confirmed that there is a prior fail loaded for comparison between the failing row and column addresses 374.

As illustrated, diagnostic column fail circuit determines from the comparison whether the same row and the same column fails in different subarrays 376, and if “yes”, then a column repair flag is set 378 to signal the column fail, which in one or more embodiments, is interpreted as a local column fail flag where the global bitline flag is not set. As illustrated, the diagnostic column fail circuit further determines from comparing the failing row and column addresses 374 whether a column fails testing across multiple rows and on a same row across different subarrays of the multiple subarrays 380, an if “yes”, sets the global bitline fail flag 382. As described herein, the set column repair flag 378 can be used to guide automated column repairs within the memory array of the integrated circuit device, and the set global bitline fail flag can be used to generate a further action to address the failing memory array issue. For instance, in one or more embodiments, the memory array can be replaced, or redesigned, for the integrated circuit device.

Those skilled in the art will note from the description provided herein that numerous inventive aspects and features are disclosed. In one or more embodiments, the diagnostic circuitry disclosed includes a fail counter circuit that increments in one mode based on each failing address, and in another mode, based on each failing data or bit detected at each failing address, thereby rendering a true failing cell count for a memory array test operation. In addition, in one or more embodiments, the diagnostic circuitry can include a column fail circuit that determines if a fail is a single bit or a column fail based on the failing row and column addresses, and log this information in a fail address register during at speed built-in self-test of the memory array.

Further, in one or more embodiments of the fail counter circuit, an associated mux control can be provided to determine the operation mode of the fail counter, that is, whether the counter operates in the address fail counter mode or the cell fail counter mode. In one or more embodiments, the built-in self-test engine can be programed to insert N no operations after each read to allow the fail counter circuit to have enough cycles to process all fails and data out when in the cell fail counter mode, allowing the built-in self-test algorithm (or pattern) to run without stopping (or interruption), counting all cell fails as it runs.

In one or more embodiments, the diagnostic column fail circuit includes logic to determine if the column fail is a local column fail or a global column fail based on the failing row and column addresses, and logs the determination as one or more status flags, such as in a fail address register, along with the failing column address. As noted herein, the functionality of the fail counter circuit and the diagnostic column fail circuit is accomplished at testing operation speed with the built-in self-test engine, absent stopping of the running of the built-in self-test pattern to process the fail data.

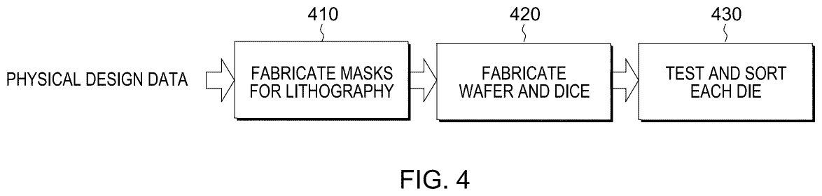

In one or more embodiments, further aspects include fabricating a physical integrated circuit, with circuitry such as described herein, in accordance with the circuit design. One non-limiting specific example that accomplishes this is described herein in connection with FIGS. 4-6. For example, the circuit design, or circuit design structure, is provided to fabrication equipment to facilitate fabrication of a physical integrated circuit in accordance with the design structure.

In one or more embodiments, a layout is prepared based on the analysis. In one or more embodiments, the layout is instantiated as a design structure. In one or more embodiments, a physical integrated circuit is fabricated in accordance with the design structure.

As noted, in one or more embodiments, the layout is instantiated as a design structure. A physical integrated circuit is then fabricated in accordance with the design structure. Refer also to the discussion below for FIGS. 4-6. FIG. 4 is a flow diagram of a design process used in semiconductor design, manufacture, and/or test. Once the physical design data is obtained, based, in part, on the design processes described herein, an integrated circuit designed in accordance therewith can be fabricated according to known processes that are generally described with reference to FIG. 4. Generally, a wafer with multiple copies of the final design is fabricated and cut (i.e., diced) such that each die is one copy of the integrated circuit. At block 410, the processes include fabricating masks for lithography based on the finalized physical layout. At block 420, fabricating the wafer includes using the masks to perform photolithography and etching. Once the wafer is diced, testing and sorting each die is performed at 430 to filter out any faulty die. Furthermore, referring to FIGS. 4-6, in one or more embodiments the at least one processor is operative to generate a design structure for the integrated circuit design in accordance with the circuit design, such as a VLSI design, and in at least some embodiments, the at least one processor is further operative to control integrated circuit manufacturing equipment to fabricate a physical integrated circuit in accordance with the design structure. Thus, the layout can be instantiated as a design structure, and the design structure can be provided to fabrication equipment to facilitate fabrication of a physical integrated circuit in accordance with the design structure. The physical integrated circuit will be improved (for example, because of proper capacitance extraction) compared to circuits designed using prior art techniques, at least under conditions where there is the same CPU time budget for the design process. To achieve similar improvements with prior-art techniques, even if possible, would require expenditure of more CPU time as compared to embodiments of the invention.

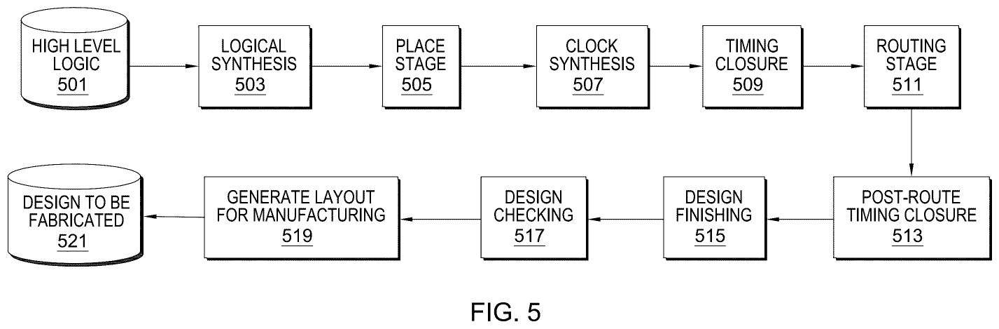

FIG. 5 depicts an example high-level Electronic Design Automation (EDA) tool flow, which is responsible for creating an optimized microprocessor (or other IC) design to be manufactured. A designer can start with a high-level logic description 501 of the circuit (e.g. VHDL or Verilog). The logic synthesis tool 503 compiles the logic and optimizes it without any sense of its physical representation, and with estimated timing information. Placement tool 505 takes the logical description and places each component, looking to minimize congestion in each area of the design. The clock synthesis tool 507 optimizes the clock tree network by cloning/balancing/buffering the latches or registers. The timing closure step 509 performs a number of optimizations on the design, including buffering, wire tuning, and circuit repowering; its goal is to produce a design which is routable, without timing violations, and without excess power consumption. Routing stage 511 takes the placed/optimized design and determines how to create wires to connect the components, without causing manufacturing violations. Post-route timing closure 513 performs another set of optimizations to resolve any violations that are remaining after the routing. Design finishing 515 then adds extra metal shapes to the netlist, to conform with manufacturing requirements. Checking steps 517 analyze whether the design is violating any requirements such as manufacturing, timing, power, electromigration or noise. When the design is clean, the final step 519 is to generate a layout for the design, representing all the shapes to be fabricated in the design to be fabricated 521.

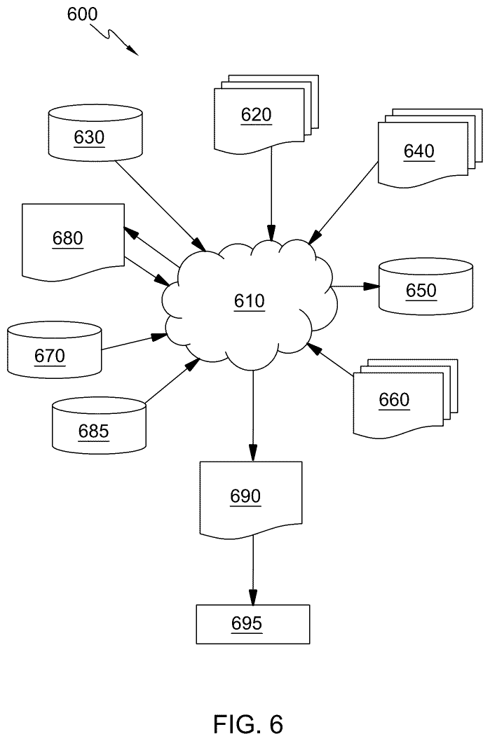

One or more embodiments integrate the timing analysis techniques herein with semiconductor integrated circuit design simulation, test, layout, and/or manufacture. In this regard, FIG. 6 shows a block diagram of an exemplary design flow 600 used for example, in semiconductor IC logic design, simulation, test, layout, and manufacture. Design flow 600 includes processes, machines and/or mechanisms for processing design structures or devices to generate logically or otherwise functionally equivalent representations of design structures and/or devices, such as those that can be analyzed using timing analysis or the like. The design structures processed and/or generated by design flow 600 may be encoded on machine-readable storage media to include data and/or instructions that when executed or otherwise processed on a data processing system generate a logically, structurally, mechanically, or otherwise function-ally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g., E-V writers), computers, or equipment for simulating design structures, any apparatus used in the manufacturing or test process, or any machines for programming functionality equivalent representations of the design structures into any medium (e.g., a machine for programming a programmable gate array).

Design flow 600 may vary depending on the type of representation being designed. For example, a design flow 600 for building an application specific IC (ASIC) may differ from a design flow 600 for designing a standard component or from a design flow 600 for instantiating the design into a programmable array, for example a programmable gate array (PGA) or a field programmable gate array (FPGA).

FIG. 6 illustrates multiple such design structures 620 that is preferably processed by a design process 610. Design structure 620 may be a logical simulation design structure generated and processed by design process 610 to produce a logically equivalent functional representation of a hardware device. Design structure 620 may also or alternatively comprise data and/or program instructions that when processed by design process 610, generate a functional representation of the physical structure of a hardware device. Whether representing functional and/or structural design features, design structure 620 may be generated using electronic computer-aided design (ECAD), such as implemented by a core developer/designer. When encoded on a gate array or storage medium of the loke, design structure 620 may be accessed and processed by one or more hardware and/or software modules within design process 610 to simulate or otherwise functionally represent an electronic component, circuit, electronic or logic module, apparatus, device, or system. As such, design structure 620 may comprise files or other data structures including human and/or machine-readable source code, compiled structures, and computer executable code structure that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages, such as Verilog and VHDL, and/or higher level design languages, such as C or C++.

Design process 610 preferably employs and incorporates hardware and/or software modules for synthesizing, translating, or otherwise processing a design/simulation functional equivalent of components, circuits, devices, or logic structures to generate a Netlist 680, which may contain design structures such as design structure 620. Netlist 680 may comprise, for example, compiled or otherwise processed data structures representing a list of wires, discrete components, logic gates, control circuits, I/O devices, modules, etc., that describes the connections to other elements and circuits in an integrated circuit design. Netlist 680 may be recorded on a machine-readable data storage medium or programmed into a programmable gate array, a compact flash, or other flash memory. Additionally, or in the alternative, the medium may be a system or cache memory, buffer space, or other suitable memory.

Design process 610 may include hardware and software modules for processing a variety of input data structure system, including Netlist 680. Such data structure types may reside, for example, within library elements 630 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 640, characterization data 650, verification data 660, design rules 670, and test data files 685, which may include input test patterns, output test results, and other testing information. Design process 610 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 610 without deviating from the scope and spirit of the invention. Design process 610 may also include modules for performing standard circuit design processes such as timing analysis, verification, design rule checking, place and route operations, etc. Improved placement can be performed as described herein.

Design process 610 employs and incorporates logic and physical design tools such as HDL compilers and simulation model build tools to process design structure 620 together with some or all of the depicted supporting data structures along with any additional mechanical design or data (if applicable), to generate a second design structure 690. Design structure 690 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 620, design structure 690 preferably comprises one or 10 more files, data structures, or other computer-encoded data or instructions that reside on data storage media and that when processed by an ECAD system generate a logically or otherwise functionally equivalent form of one or more IC designs or the like. In one embodiment, design structure 690 may comprise a compiled, executable HDL simulation model that functionally simulates the devices to be analyzed.

Design structure 690 may also employ a data format used for the exchange of layout data of integrated circuits and/or symbolic data format (e.g. information stored in a GDSII (GDS2), GL1, OASIS, map files, or any other suitable format for storing such design data structures). Design structure 690 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 690 may then proceed to a stage 695 where, for example, design structure 690: proceeds to tape-out, is released to manufacturing, is released to a mask house, is sent to another design house, is sent back to the customer, etc.

The computing environments described herein are only examples of computing environments that can be used. One or more aspects of the present disclosure may be used with many types of environments. The computing environments provided herein are only examples. Each computing environment is capable of being configured to include one or more aspects of the present disclosure.

Other aspects, variations and/or embodiments are possible.

In addition to the above, one or more aspects may be provided, offered, deployed, managed, serviced, etc. by a service provider who offers management of customer environments. For instance, the service provider can create, maintain, support, etc. computer code and/or a computer infrastructure that performs one or more aspects for one or more customers. In return, the service provider may receive payment from the customer under a subscription and/or fee agreement, as examples. Additionally, or alternatively, the service provider may receive payment from the sale of advertising content to one or more third parties.

In one aspect, an application may be deployed for performing one or more embodiments. As one example, the deploying of an application comprises providing computer infrastructure operable to perform one or more embodiments.

As a further aspect, a computing infrastructure may be deployed comprising integrating computer-readable code into a computing system, in which the code in combination with the computing system is capable of performing one or more embodiments.

Yet a further aspect, a process for integrating computing infrastructure comprising integrating computer-readable code into a computer system may be provided. The computer system comprises a computer-readable medium, in which the computer medium comprises one or more embodiments. The code in combination with the computer system is capable of performing one or more embodiments.

Although various embodiments are described above, these are only examples. For example, other memory access instructions may be used. Further, other predictors may be used, including, but not limited to, other examples of a counter table and/or a global counter. Many variations are possible.

Various aspects and embodiments are described herein. Further, many variations are possible without departing from a spirit of aspects of the present disclosure. It should be noted that, unless otherwise inconsistent, each aspect or feature described and/or claimed herein, and variants thereof, may be combinable with any other aspect or feature.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of one or more embodiments has been presented for purposes of illustration and description but is not intended to be exhaustive or limited to in the form disclosed. Many modifications and variations will be apparent to those of ordinary skill in the art. The embodiment was chosen and described in order to best explain various aspects and the practical application, and to enable others of ordinary skill in the art to understand various embodiments with various modifications as are suited to the particular use contemplated.

What is claimed is:

1. An integrated circuit device comprising:
a memory array including an array of memory cells arranged in rows and columns;
circuitry operatively coupled to the memory array, the circuitry including a fail counter circuit, and the circuitry being configured to facilitate:
performing a testing operation on the memory array, with the fail counter circuit being operable during the testing operation in a selected one fail counter mode of a plurality of fail counter modes, the plurality of fail counter modes including:
an address fail counter mode to determine a number of failing addresses of the memory array during the testing operation; and
a cell fail counter mode to determine a number of failing memory cells of the memory array during the testing operation.

2. The integrated circuit device of claim 1, wherein the fail counter circuit is configured with a fail counter control to facilitate selection of the one fail counter mode of the plurality of fail counter modes.

3. The integrated circuit device of claim 1, wherein the circuitry comprises built-in self-test circuitry and the selected one fail counter mode comprises the address fail counter mode, and wherein performing the testing operation on the memory array with the fail counter circuit in the address fail counter mode includes running a built-in self-test pattern on the memory array and incrementing a fail counter of the fail counter circuit based on each failing address during the testing operation.

4. The integrated circuit device of claim 3, wherein the fail counter circuit determines the number of failing addresses in the address fail counter mode at testing operation speed, absent a stopping of the running of the built-in self-test pattern.

5. The integrated circuit device of claim 1, wherein the circuitry comprises built-in self-test circuitry and the selected one fail counter mode comprises the cell fail counter mode, and wherein performing the testing operation on the memory array with the fail counter circuit in the cell fail counter mode includes running a built-in self-test pattern on the memory array and incrementing a fail counter of the fail counter circuit based on each failing memory cell during the testing operation.

6. The integrated circuit device of claim 5, wherein the fail counter circuit determines the number of failing memory cells in the cell fail counter mode at testing operation speed, absent a stopping of the running of the built-in self-test pattern.

7. The integrated circuit device of claim 6, wherein the circuitry is configured to facilitate performing the testing operation on the memory array in the cell fail counter mode absent stopping running of the built-in self-test pattern by inserting N no-operation cycles in the built-in self-test pattern used in the testing operation after each memory array read of the testing operation to facilitate the fail counter circuit processing up to N potential failing cells at each memory array address, wherein each memory array address includes N bits.

8. The integrated circuit device of claim 1, wherein the memory array includes multiple subarrays of the memory cells arranged in rows and columns, and wherein the circuitry further includes a diagnostic column fail circuit, with the diagnostic column fail circuit being operable during the testing operation to determine a type of column fail, the type of column fail being one of a local column fail and a global column fail, wherein:
the local column fail is determined by the diagnostic column fail circuit where a column fails testing across multiple rows that are different rows across a same subarray and across different subarrays of the multiple subarrays; and
the global column fail is determined by the diagnostic column fail circuit where a column fails testing across multiple rows and on a same row across different subarrays of the multiple subarrays.

9. The integrated circuit device of claim 8, wherein performing the testing operation on the memory array includes running a built-in self-test pattern on the memory array, and wherein the diagnostic column fail circuit determines the type of the column fail during the testing operation at testing operation speed, absent a stopping of the running of the built-in self-test pattern.

10. An integrated circuit device comprising:
a memory array including multiple subarrays of memory cells arranged in rows and columns;
circuitry operatively coupled to the memory array, the circuitry including a diagnostic column fail circuit, and the circuitry being configured to facilitate:
performing a testing operation on the memory array, with the diagnostic column fail circuit being operable during the testing operation to determine a type of a column fail, the type of column fail being one of a local column fail and a global column fail, wherein:
the local column fail is determined by the diagnostic column fail circuit where a column fails testing across multiple rows that are different rows across a same subarray and across different subarrays of the multiple subarrays; and
the global column fail is determined by the diagnostic column fail circuit where a column fails testing across multiple rows and on a same row across different subarrays of the multiple subarrays.

11. The integrated circuit device of claim 10, wherein performing the testing operation on the memory array includes running a built-in self-test pattern on the memory array, and wherein the diagnostic column fail circuit determines the type of the column fail during the testing operation at testing operation speed, absent a stopping the running of the built-in self-test pattern.

12. The integrated circuit device of claim 10, wherein the diagnostic column fail circuit is configured to set a column repair flag where the local column fail is determined by the diagnostic column fail circuit.

13. The integrated circuit device of claim 10, wherein the diagnostic column fail circuit is configured to set a global bitline fail flag where the global column fail is determined by the diagnostic column fail circuit.

14. The integrated circuit device of claim 10, wherein the circuitry further includes a fail counter circuit configured with a fail counter control to facilitate selection of one of a plurality of fail counter modes, the plurality of fail counter modes including:
an address fail counter mode to determine a number of failing addresses of the memory array during the testing operation; and
a cell fail counter mode to determine a number of failing memory cells of a memory array during the testing operation.

15. The integrated circuit device of claim 14, wherein the circuitry comprises built-in self-test circuitry and the selected one fail counter mode comprises the address fail counter mode, and wherein performing the testing operation on the memory array with the fail counter circuit in the address fail counter mode includes running a built-in self-test pattern on the memory array and incrementing a fail counter of the fail counter circuit based on each failing address during the testing operation.

16. The integrated circuit device of claim 14, wherein the circuitry comprises built-in self-test circuitry and the selected one fail counter mode comprises the cell fail counter mode, and wherein performing the testing operation on the memory array with the fail counter circuit in the cell fail counter mode includes running a built-in self-test pattern on the memory array and incrementing a fail counter of the fail counter circuit based on each failing memory cell during the testing operation.

17. A method of testing an integrated circuit device, the integrated circuit device having a memory array including an array of memory cells arranged in rows and columns and circuitry operatively coupled to the memory array, the circuitry including a fail counter circuit, the method comprising:
selecting a fail counter mode of the fail counter circuit from a plurality of fail counter modes, the plurality of fail counter modes including:
an address fail counter mode to determine a number of failing addresses of the memory array during a testing operation; and
a cell fail counter mode to determine a number of failing memory cells of the memory array during the testing operation; and
performing the testing operation on the memory array, with the fail counter circuit operable during the testing operation in the selected one of the plurality of fail counter modes.

18. The method of claim 17, wherein the circuitry comprises built-in self-test circuitry and the selected fail counter mode comprises the address fail counter mode, and wherein performing the testing operation on the memory array with the fail counter circuit in the address fail counter mode includes running a built-in self-test pattern on the memory array and incrementing a fail counter of the fail counter circuit based on each failing address during the testing operation.

19. The method of claim 17, wherein the circuitry comprises built-in self-test circuitry and the selected fail counter mode comprises the cell fail counter mode, and wherein performing the testing operation on the memory array with the fail counter circuit in the cell fail counter mode includes running a built-in self-test pattern on the memory array and incrementing a fail counter of the fail counter circuit based on each failing memory cell during the testing operation.

20. The method of claim 17, wherein the memory array includes multiple subarrays of the memory cells arranged in rows and columns, and wherein the circuitry further includes a diagnostic column fail circuit, with the diagnostic column fail circuit being operable during the testing operation to determine a type of column fail, the type of column fail being one of a local column fail and a global column fail, wherein:
the local column fail is determined by the diagnostic column fail circuit where a column fails testing across multiple rows that are different rows across a same subarray and across different subarrays of the multiple subarrays; and
the global column fail is determined by the diagnostic column fail circuit where a column fails testing across multiple rows and on a same row across different subarrays of the multiple subarrays.
